(19) United States
(12) Patent Application Publication
(10) Pub. No.: US 2026/0313812 A1
(43) Pub. Date: Oct. 8, 2026

(54) CIRCUIT BOARD ASSEMBLY AND METHOD OF MANUFACTURING DISPLAY USING THE SAME

(71) Applicant: SAMSUNG DISPLAY CO., LTD., Yongin-Si (KR)

(72) Inventor: Joo Young PARK, Yongin-si (KR)

(21) Appl. No.: 19/293,041

(22) Filed: Aug. 7, 2025

(30) Foreign Application Priority Data
Apr. 4, 2025 (KR) 10-2025-0044300

(51) Int. Cl. H05K 5/00; H05K 3/28

(52) U.S. Cl. CPC H05K 5/0026; H05K 3/28

(57) ABSTRACT

A circuit board assembly includes a circuit board member, a first protection member disposed on at least a portion of an upper surface of the circuit board member, a first adhesive layer disposed between the circuit board member and the first protection member, and a support member disposed on a side of the first protection member and supporting at least a portion of a lower surface of the circuit board member.

### CROSS-REFERENCE TO RELATED APPLICATIONS

This application claims priority under 35 U.S.C. § 119 to Korean Patent Application No. 10-2025-0044300, filed on Apr. 4, 2025, the disclosure of which is incorporated by reference herein in its entirety.

### TECHNICAL FIELD

Embodiments of the present disclosure relate to a circuit board assembly and a method of manufacturing a display using the same.

### DISCUSSION OF RELATED ART

Various types of display devices are used in various applications, such as, for example, mobile devices, TVs, and monitors.

A display panel, such as, for example, an organic light-emitting diode (OLED) or a liquid crystal display (LCD) display panel utilizes an electrical connection with an external circuit for high-resolution image output and signal processing. To this end, a process of connecting a flexible printed circuit (FPC) to a back surface of the display panel is implemented in a manufacturing process.

### SUMMARY

Embodiments of the present disclosure relate to a circuit board assembly capable of preventing sagging of a flexible printed circuit (FPC) and a method of manufacturing a display using the same.

According to various embodiments of the present disclosure, a circuit board assembly includes a circuit board member, a first protection member disposed on (e.g., covering) at least a portion of an upper surface of the circuit board member, a first adhesive layer disposed between the circuit board member and the first protection member, and a support member disposed on a side of the first protection member and supporting at least a portion of a lower surface of the circuit board member.

In some embodiments, the support member is connected to the first protection member at an outside of an edge of the circuit board member.

In some embodiments, the support member supports an area of the circuit board member in which the first adhesive layer is not disposed.

In some embodiments, the support member includes a mounting portion supporting at least a portion of the lower surface of the circuit board member, and a connection portion connecting the mounting portion and the first protection member.

In some embodiments, the circuit board assembly further includes an adhesive member attaching the support member to a lower surface of the first protection member.

In some embodiments, the connection portion is connected to the first protection member through the adhesive member.

In some embodiments, the circuit board assembly further includes a second protection member covering at least a portion of the lower surface of the circuit board member, and the mounting portion is in contact with the second protection member and support the circuit board member.

In some embodiments, a thickness of the adhesive member is greater than or about equal to a sum of a thickness of the first adhesive layer and a thickness of the circuit board member.

In some embodiments, the connection portion overlaps the adhesive member in a vertical direction, and the mounting portion overlaps the second protection member in the vertical direction.

In some embodiments, the mounting portion is disposed in parallel to the first protection member.

In some embodiments, an area of the support member increases as the support member extends from the connection portion to the mounting portion.

In some embodiments, the support member extends from the side of the first protection member toward the lower surface of the circuit board member.

In some embodiments, the connection portion is inclined downward as the connection portion extends from the first protection member to the mounting portion.

In some embodiments, the mounting portion elastically supports the circuit board member through the connection portion.

In some embodiments, the support member is formed integrally with the first protection member.

In some embodiments, a height of the connection portion is greater than or about equal to a sum of a thickness of the first adhesive layer and a thickness of the circuit board member.

In some embodiments, the circuit board member includes a body portion extending in a first direction and a tail portion extending from an end of the body portion in a second direction different from the first direction, and the support member extends from the side of the first protection member in the first direction and supports the tail portion of the circuit board member.

According to various embodiments of the present disclosure, a display device includes a circuit board member, a first protection member disposed on at least a portion of an upper surface of the circuit board member, a first adhesive layer disposed between the circuit board member and the first protection member, and a support member disposed on a side of the first protection member and supporting at least a portion of a lower surface of the circuit board member.

According to various embodiments of the present disclosure, there is provided a method of manufacturing a display including performing a support operation including arranging a first protection member on an upper surface of a circuit board member and supporting at least a portion of a lower surface of the circuit board member through a support member disposed on a side of the first protection member, and performing a transfer operation including transferring the circuit board member in a state in which a side of the circuit board member is supported by the support member.

In some embodiments, the method further includes performing a support release operation including removing the first protection member and the support member from the circuit board member on which the transfer is completed.

In some embodiments, in the support operation, the support member is connected to the first protection member at an outside of an edge of the circuit board member and extends toward and supports the circuit board member.

According to various embodiments of the present disclosure, sagging of an FPC that may occur in a transfer process can be prevented.

In addition, various embodiments of the present disclosure can prevent sagging of the FPC without a complex device, resulting in improvements in efficiency relating to the cost and manufacturing process of the device.

### BRIEF DESCRIPTION OF THE DRAWINGS

The above and other features of the present disclosure will become more apparent by describing in detail embodiments thereof with reference to the accompanying drawings.

FIG. 1A is a top view of a circuit board assembly according to an embodiment of the present disclosure.

FIG. 1B is a bottom view of a circuit board assembly according to an embodiment of the present disclosure.

FIG. 2 is an enlarged perspective view of a portion A in FIG. 1B.

FIG. 3 is an exploded perspective view of a circuit board assembly according to an embodiment of the present disclosure.

FIG. 4 schematically illustrates a support structure of a circuit board member by a support member in a circuit board assembly according to an embodiment of the present disclosure.

FIG. 5A is a top view of a circuit board assembly according to an embodiment of the present disclosure.

FIG. 5B is a bottom view of a circuit board assembly according to an embodiment of the present disclosure.

FIG. 6 is an enlarged perspective view of portions B and B’ of FIGS. 5A and 5B.

FIG. 7 is an exploded perspective view of a circuit board assembly according to an embodiment of the present disclosure.

FIG. 8 schematically illustrates a support structure of a circuit board member by a support member in a circuit board assembly according to an embodiment of the present disclosure.

FIG. 9 is a flowchart illustrating a method of manufacturing a display device according to an embodiment of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

As used herein, the singular form may include the plural form unless the context clearly dictates otherwise.

It will be understood that terms such as “comprise,” “include,” and “have,” when used herein, specify a presence of stated features, integers, steps, operations, elements, and/or components, but do not preclude the presence or addition of one or more other features, integers, steps, operations, elements, components, and/or groups thereof.

It will be understood that the terms “first,” “second,” “third,” etc. are used herein to distinguish one element from another, and the elements are not limited by these terms. Thus, a “first” element in an embodiment may be described as a “second” element in another embodiment.

It will be understood that descriptions of features or aspects within each embodiment should typically be considered as available for other similar features or aspects in other embodiments, unless the context clearly indicates otherwise.

As used herein, the term "and/or" includes any and all combinations of one or more of the associated listed items. Expressions such as “at least one of,” when preceding a list of elements, modify the entire list of elements and do not modify the individual elements of the list.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

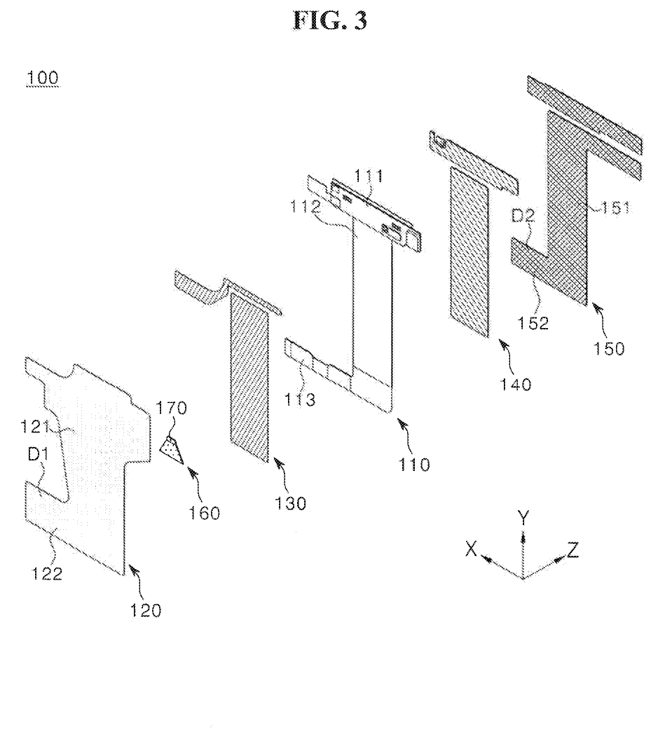

Hereinafter, a direction (e.g., the Z direction in FIG. 3) in which a first protection member and a second protection member are stacked on a circuit board member may be described as a vertical direction. In addition, a direction (e.g., the Y direction in FIG. 3) in which a body portion extends from a panel coupling portion in the circuit board member may be described as a first direction, and a direction (e.g., the X direction in FIG. 3) in which a tail portion extends from the body portion may be described as a second direction.

Hereinafter, a circuit board assembly according to various embodiments of the present disclosure is described in detail with reference to the accompanying drawings.

Embodiments of the present disclosure provide a circuit board assembly for use in, e.g., display devices. For example, embodiments relate to an improved support structure for a flexible circuit board that may prevent sagging during transport and handling, while enabling clean removal prior to final panel integration.

For example, in a manufacturing processes for flexible printed circuit boards (FPCs) according to a comparative example, sagging or deformation may occur if portions of the circuit board are not secured, especially in regions where no adhesive is applied to avoid contaminating terminal parts or mounting regions. While protective members could be attached to the top or bottom surfaces of the circuit board using adhesive layers, these protection members alone may be insufficient to prevent sagging of unadhered areas during handling.

To address this, embodiments of the present disclosure provide a circuit board assembly including a support member coupled to a protective member and extending beneath the circuit board to mechanically support regions lacking adhesive coverage. In embodiments, the support member may be directly attached to the protective member or joined via an adhesive layer, and may contact the circuit board directly or through a lower protection member. This structure may improve handling reliability and manufacturing efficiency without interfering with the board’s eventual coupling to the display panel.

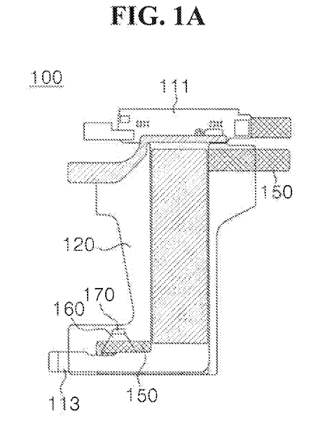

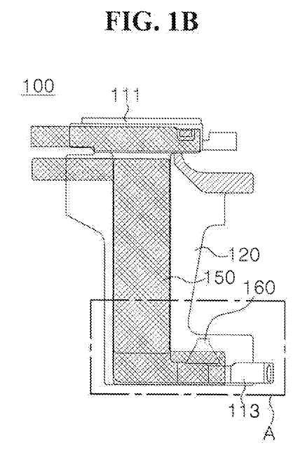

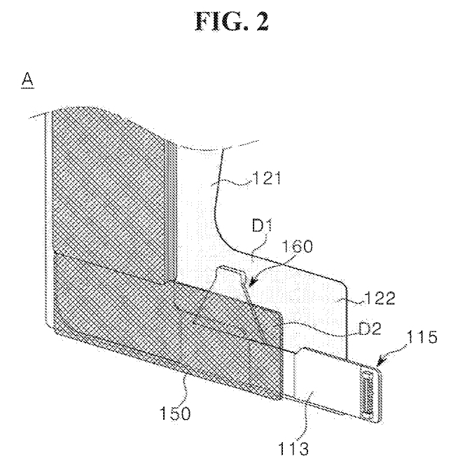

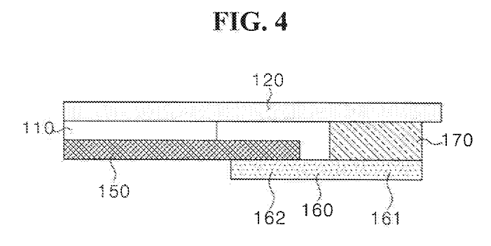

FIG. 1A is a top view of a circuit board assembly according to an embodiment of the present disclosure. FIG. 1B is a bottom view of a circuit board assembly according to an embodiment of the present disclosure. FIG. 2 is an enlarged perspective view of a portion A in FIG. 1B. FIG. 3 is an exploded perspective view of a circuit board assembly according to an embodiment of the present disclosure. FIG. 4 schematically illustrates a support structure of a circuit board member 110 by a support member 160 in a circuit board assembly according to an embodiment of the present disclosure.

Referring to FIGS. 1A-1B and 2 to 4, a circuit board assembly 100 according to various embodiments of the present disclosure may include a circuit board member 110, a first adhesive layer 130, a first protection member 120, a second adhesive layer 140, a second protection member 150, and a support member 160.

The circuit board member 110 may be coupled to a back surface of a display panel in a display device and may drive the display panel. The circuit board member 110 may apply an electrical signal that drives the display panel. For example, the circuit board member 110 may be equipped with a driving integrated circuit that generates a data signal and a gate signal to drive pixels of the display panel on a circuit board including a single layer or multiple layers of circuit patterns, and supplies the data signal and the gate signal to data lines and gate lines of the display device.

The circuit board member 110 may be a rigid printed circuit board (PCB) or a flexible printed circuit board (FPCB) with flexibility.

For example, the circuit board member 110 may be implemented using a chip-on-glass (COG) method or a chip-on-film (COF) method. For example, the circuit board member 110 may be implemented using a flexible printed circuit (FPC) to provide flexibility. However, this is an example and is not limited thereto.

Referring to FIG. 3, in an embodiment of the present disclosure, an end area of the circuit board member 110 may include a panel coupling portion 111 coupled to the back surface of the display panel. For example, a connector that connects to the panel may be disposed in the panel coupling portion 111, and components, such as, for example, a capacitor, a resistor, and an inductor, may be disposed in the panel coupling portion 111.

For example, the circuit board member 110 may include a body portion 112 extending from the panel coupling portion 111 in the first direction (e.g., the Y direction in FIG. 3) and a tail portion 113 extending from an end of the body portion 112 in the second direction (e.g., the X direction in FIG. 3) different from the first direction. For example, the second direction in which the tail portion 113 extends may be a direction perpendicular to the first direction, but is not limited thereto.

Each of the body portion 112 and the tail portion 113 may have a selectable width. For example, the body portion 112 may have a first width in a direction perpendicular to the first direction in which the body portion 112 extends, and the tail portion 113 may have a second width in a direction perpendicular to the second direction in which the tail portion 113 extends.

The body portion 112 and the tail portion 113 may have wiring forming the circuit pattern. In addition, a terminal part (e.g., 115 of FIG. 2) that connects to an external device (e.g., a main board) may be disposed in an end area of the tail portion 113 of the circuit board member 110. However, the body portion 112 and the tail portion 113 of the circuit board member 110 described herein are an example and are not necessarily limited to the structure described above.

The circuit board member 110 may formed with a thin thickness, which may reduce space consumption within the display device. For example, the circuit board member 110 may be configured to provide flexibility in addition to thinness by using an FPC.

In some implementations, forming the circuit board member 110 with a thin thickness may contribute to increased flexibility, but may also introduce structural instability during handling. For example, the combination of reduced rigidity and elongated geometry may cause portions of the circuit board member 110 to sag or bend under their own weight when the circuit board member 110 is supported only at one or more discrete points by a transport device.

In a manufacturing process of the display device, the circuit board member 110 may be manufactured at a separate location from the display panel, and then transferred toward the display panel that is pre-arranged on a stage. Hence, the circuit board member 110 may be coupled to the back surface of the display panel.

For example, since the circuit board member 110 is provided in the form of a thin plate, an end of the circuit board member 110 may sag in a transport process. For example, in the circuit board member 110, sagging may occur due to gravity at a portion far from a point held by a transport device. In a case in which the circuit board member 110 applies the FPC to secure the thin thickness and flexibility, there is a possibility that the circuit board member 110 may sag as the circuit board member 110 goes to its end. Since it is difficult to directly hold the tail portion 113 of the circuit board member 110 by the transport device in the transport process so as to prevent deformation of the terminal part, the possibility of sagging may increase.

Embodiments of the present disclosure provide a circuit board assembly that can prevent sagging of the circuit board member 110 in the transport process of the circuit board member 110 through the transport device.

In this context, relying solely on the first protection member 120 and the first adhesive layer 130 to reinforce the circuit board member 110 may be insufficient. For example, to avoid contamination or mechanical interference with sensitive portions such as the terminal part 115 at the end of the tail portion 113, certain areas of the circuit board member 110 may be left unattached to the first protection member 120. These unattached areas may lack adhesive reinforcement, and may therefore be more prone to sagging or deflection during movement.

To address this, embodiments of the present disclosure provide a support member 160 that is positioned on a side of the first protection member 120 and extends toward the lower surface of the circuit board member 110. The support member 160 may mechanically support areas of the circuit board member 110 not bonded by adhesive, such as the tail portion 113, which may enable safe and stable transport of the circuit board member 110 without requiring a more complex holding mechanism or risking damage to the exposed terminal region.

Herein, it may be described that the support member 160 supports a side of the end of the circuit board member 110. This is an example, and a position of the support member 160 is not limited thereto. For example, the support member 160 can be applied to any part of the circuit board member 110 that may sag during the process of being transported by the transport device.

The transport process of the circuit board member 110 may be performed in a state in which a separately provided transport device holds at least one point of the circuit board member 110.

According to embodiments, depending on the layout of the circuit board member 110 and the direction of transport, the location of the sag-prone region may vary. Because the support member 160 may be positioned adjacent to, rather than directly on, the circuit board member 110 in embodiments, it can be selectively positioned to accommodate variations in shape, size, or orientation of the circuit board member 110. This structural flexibility may improve the applicability of the assembly across a range of display device configurations.

Referring to FIGS. 1 and 2, the first protection member 120 may be disposed on an upper surface of the circuit board member 110. The first protection member 120 may be disposed in a plate shape so as to cover at least a portion of the upper surface of the circuit board member 110. For example, the first protection member 120 may cover an upper surface of the body portion 112 of the circuit board member 110. For example, the first protection member 120 may cover at least a portion of an upper surface of the tail portion 113 along with the upper surface of the body portion 112 of the circuit board member 110.

For example, the first protection member 120 may include a first body protection portion 121 disposed on an upper portion of the body portion 112 of the circuit board member 110 and a first tail protection portion 122 that extends from the first body protection portion 121 and is disposed on an upper portion of the tail portion 113 of the circuit board member 110.

For example, the first body protection portion 121 may cover an area at least wider than the width of the body portion 112, and the first tail protection portion 122 may cover an area at least wider than the width of the tail portion 113.

For example, the first protection member 120 may overlap at least a portion of the circuit board member 110 in the vertical direction. For example, the first protection member 120 may include a first dummy area D1 of which at least a portion is disposed outside an edge of the circuit board member 110, and the first dummy area D1 does not overlap the circuit board member 110 in the vertical direction.

The first protection member 120 may be attached to the upper surface of the circuit board member 110 through the first adhesive layer 130. For example, the first protection member 120 may include a portion that that is not attached to the upper surface of the circuit board member 110 while covering the upper surface of the circuit board member 110. For example, the first protection member 120 may not be attached to the panel coupling portion 111 while covering at least a portion of the panel coupling portion 111 of the circuit board member 110.

For example, the first body protection portion 121 of the first protection member 120 may be attached to the upper surface of the body portion 112.

For example, the first tail protection portion 122 of the first protection member 120 may include a portion that is not attached to the upper surface of the tail portion 113 while covering at least a portion of the upper surface of the tail portion 113. Since the first tail protection portion 122 includes the portion that is not attached to the tail portion 113, the first tail protection portion 122 can prevent the terminal part disposed at an end of the tail portion 113 from being deformed by the first protection member 120 or contaminated by the first adhesive layer 130.

In a case in which the tail portion 113 corresponding to the end of the circuit board member 110 is not attached to the first protection member 120, the tail portion 113 may sag in the transport process. However, in the disclosure, as illustrated in FIG. 2, the tail portion 113 may be structurally supported by the support member 160 disposed on the first protection member 120, and thus the support member 160 can prevent sagging of the tail portion 113.

Referring to an example, a portion of the first tail protection portion 122 is not adhered to the tail portion 113, which may prevent the terminal part 115 from being exposed to adhesive materials or mechanical stress during transport. However, this non-adhered condition could result in a lack of structural support at the end of the circuit board member 110. The support member 160, which extends from the first protection member 120 and contacts the underside of the tail portion 113 according to embodiments, may structurally compensate for this lack of adhesion by supporting the tail portion 113 from below.

As a result, the support member 160 may enable the terminal end of the circuit board member 110 to maintain a planar or stable orientation during transfer, even in the absence of adhesive bonding. This design may avoid terminal deformation while simplifying the removal process after the circuit board member 110 is mounted on the display panel.

In some embodiments, the first protection member 120 may be formed with a thickness greater than that of the circuit board member 110, such that the first protection member 120 provides structural reinforcement without being easily deformed during handling or transport. This thickness difference may contribute to the ability of the first protection member 120 to resist bending and to stabilize the thinner, more flexible circuit board member 110, for example, when used in combination with the support member 160 to support portions of the circuit board member 110 that are not adhered by the first adhesive layer 130.

The first protection member 120 may be detachably coupled to the upper surface of the circuit board member 110 through the first adhesive layer 130. After the circuit board member 110 is transported to the display panel, the first protection member 120 may be removed from the circuit board member 110 together with the support member 160 described below.

The first protection member 120 may have a rigidity greater than a rigidity of the circuit board member 110. The first protection member 120 may be attached to the body portion 112 of the circuit board member 110 through the first adhesive layer 130, thereby preventing sagging of the body portion 112 of the circuit board member 110 through an adhesive force of the first adhesive layer 130.

In an embodiment, the connection between the support member 160 and the first protection member 120 may allow the support structure to be removed together as a unit, without applying direct force to the circuit board member 110 itself. This configuration may aid in the removal process by not leaving behind adhesive residue, introducing warping, or compromising the structural or electrical integrity of the circuit board member 110.

The first protection member 120 can prevent the circuit board member 110 from being damaged by an exposure to an external environment. The first protection member 120 may be directly held by the transport device in the transport process of the circuit board member 110.

The first protection member 120 can prevent sagging of the circuit board member 110 by supporting a side of the circuit board member 110 through the support member 160 described below.

Referring to FIG. 3, the first adhesive layer 130 may be disposed between the circuit board member 110 and the first protection member 120. The first adhesive layer 130 may be applied to the upper surface of the circuit board member 110 to attach the first protection member 120 to the circuit board member 110. The first adhesive layer 130 may include an organic adhesive, such as, for example, a pressure sensitive adhesive and an optically clear adhesive. For example, the first adhesive layer 130 may include adhesive materials, such as polyurethane-based, polyacrylic-based, polyester-based, polyepoxy-based, and polyvinyl acetate-based, but is not limited thereto.

For example, the first adhesive layer 130 may be applied to at least a portion of the upper surface of the circuit board member 110. In an embodiment, the first adhesive layer 130 is not applied to a portion of the upper surface of the circuit board member 110. For example, in an embodiment, the first adhesive layer 130 is not applied to at least a portion of the panel coupling portion 111 and the upper surface of the tail portion 113 of the circuit board member 110. Since the components and the terminal part may be disposed in the panel coupling portion 111 and the tail portion 113, the components and the terminal part may be prevented from being contaminated by the first adhesive layer 130 during the manufacturing process.

However, since the portion of the circuit board member 110, to which the first adhesive layer 130 is not applied, is not attached to the first protection member 120, sagging of the portion may occur in a case in which the transport device holds the circuit board member 110 through the first protection member 120.

The support member 160 may be disposed on a side of the first protection member 120, which may prevent sagging of the circuit board member 110.

The support member 160 may be disposed on the side of the first protection member 120 to support the circuit board member 110. For example, the support member 160 may support at least a portion of a lower surface of the circuit board member 110.

In an embodiment of the disclosure, the support member 160 may be connected to the first protection member 120 at the outside of the edge of the circuit board member 110.

An end of the support member 160 may be connected to the first protection member 120 at the outside of the edge of the circuit board member 110, and another end of the support member 160 may extend toward the circuit board member 110. For example, the other end of the support member 160 may extend toward the lower surface of the circuit board member 110 such that at least a portion of the lower surface of the circuit board member 110 is supported by the mounting portion 162 and the support member 160.

For example, the end of the support member 160 may be disposed on the side of the first tail protection portion 122 of the first protection member 120. For example, a connection portion 161 of the support member 160 may be connected to the dummy area D1 of the first tail protection portion 122.

The support member 160 may support at least a portion of the lower surface of the circuit board member 110. For example, as at least a portion of the lower surface of the circuit board member 110 is mounted on the support member 160, the circuit board member 110 can be supported by the support member 160. For example, the lower surface of the circuit board member 110 may be in surface contact with the support member 160 and may be mounted on the support member 160, but is not limited thereto. For example, the edge of the circuit board member 110 may also be mounted on the support member 160.

The support member 160 may support an area of the circuit board member 110 where the first adhesive layer 130 is not disposed. For example, the support member 160 may support an area of the tail portion 113 of the circuit board member 110 where the first adhesive layer 130 is not disposed.

In an embodiment of the disclosure, in a case in which the body portion 112 of the circuit board member 110 extends in the first direction and the tail portion 113 extends from the end of the body portion 112 in the second direction different from the first direction, the support member 160 may extend from a side of the first protection member 120 in the first direction parallel to the body portion 112 to support the tail portion 113 of the circuit board member 110.

The support member 160 may include a mounting portion 162 supporting at least a portion of the lower surface of the circuit board member 110 and the connection portion 161 connecting the mounting portion 162 and the first protection member 120.

Referring to FIG. 4, in an embodiment, the support member 160 may further include an adhesive member 170 that attaches the support member 160 to a lower surface of the first protection member 120.

The adhesive member 170 may be disposed between the first protection member 120 and the support member 160 at a position spaced apart from the first adhesive layer 130. The connection portion 161 of the support member 160 may be connected to the first protection member 120 through the adhesive member 170. For example, the connection portion 161 of the support member 160 may be attached to the first dummy area D1 of the first tail protection portion 122 through the adhesive member 170.

The adhesive member 170 may have a selectable thickness between the first protection member 120 and the support member 160. The thickness of the adhesive member 170 may indicate a height of the adhesive member 170 in the vertical direction. For example, the thickness of the adhesive member 170 may be greater than or about equal to a sum of a thickness of the first adhesive layer 130 and a thickness of the circuit board member 110. For example, in a case in which the support member 160 directly supports the lower surface of the circuit board member 110, the thickness of the adhesive member 170 may be at least about equal to the sum of the thickness of the first adhesive layer 130 and the thickness of the circuit board member 110. In a case in which the support member 160 supports the circuit board member 110 through the second protection member 150 described below, the thickness of the adhesive member 170 may be greater than the sum of the thickness of the first adhesive layer 130 and the thickness of the circuit board member 110.

The adhesive member 170 may include an organic adhesive, such as, for example, a pressure sensitive adhesive and an optically clear adhesive. For example, the adhesive member 170 may include adhesive materials, such as polyurethane-based, polyacrylic-based, polyester-based, polyepoxy-based, and polyvinyl acetate-based, but is not limited thereto.

In an embodiment, the support member 160 may be provided as a separate component from the first protection member 120 and may be attached to the first protection member 120 by the adhesive member 170. For example, the connection portion 161 of the support member 160 may be attached to the side of the first protection member 120 by the adhesive member 170.

In an embodiment, the support member 160 may be configured such that the mounting portion 162 extends toward the circuit board member 110 in a state in which the connection portion 161 is attached to the first protection member 120, and may support the circuit board member 110 through the mounting portion 162, which may prevent sagging of the circuit board member 110.

In an embodiment, the mounting portion 162 of the support member 160 may directly support the lower surface of the circuit board member 110. In an embodiment, the mounting portion 162 may support the circuit board member 110 through the second protection member 150 disposed on the lower surface of the circuit board member 110.

In an embodiment, the connection portion 161 of the support member 160 may overlap the adhesive member 170 in the vertical direction, and the mounting portion 162 of the support member 160 may overlap the circuit board member 110 or the second protection member 150 in the vertical direction.

For example, at least a portion of the lower surface of the circuit board member 110 may be mounted on the mounting portion 162 of the support member 160. For example, the lower surface of the circuit board member 110 may be in contact (e.g., direct contact) with at least a portion of an upper surface of the mounting portion 162, but is not limited thereto. For example, an edge of the lower surface of the circuit board member 110 may be mounted on the upper surface of the mounting portion 162.

For example, at least a portion of the second protection member 150 disposed on the lower surface of the circuit board member 110 may be mounted on the mounting portion 162 of the support member 160. For example, the lower surface of the second protection member 150 may be in contact (e.g., direct contact) with at least a portion of the upper surface of the mounting portion 162, but is not limited thereto. For example, an edge of the second protection member 150 may be mounted on the upper surface of the mounting portion 162.

Embodiments are described herein in which the circuit board member 110 or the second protection member 150 is in contact (e.g., direct contact) with the mounting portion 162, or in which an edge of either member is mounted on the mounting portion 162. However, this represents only one example of how the circuit board member 110 or the second protection member 150 may be structurally supported by the mounting portion 162, and is not limiting. Other configurations that enable either of these members to be supported on the mounting portion 162, whether by direct contact or other mechanical means, may be used in some embodiments.

In an embodiment, the support member 160 may be disposed in parallel to the first protection member 120. For example, the support member 160 may be disposed in a plate shape. According to embodiments, as the support member 160 is provided in a flat plate shape, the cost and/or time for processing the support member 160 into a complex shape can be reduced.

In an embodiment, a width of the support member 160 may increase as the support member 160 extends from the connection portion 161 to the mounting portion 162. For example, the support member 160 may be disposed such that an area of the mounting portion 162 is wider than an area of the connection portion 161. Since the area of the mounting portion 162 is wider than the area of the connection portion 161, the circuit board member 110 or the second protection member 150 can be stably mounted on the mounting portion 162, and the mounting portion 162 can be easily coupled to the circuit board member 110 or the second protection member 150 during the assembly process of the circuit board member 110. However, the shape of the support member 160 is merely an example and is not limited thereto, and any shape that can be connected to the first protection member 120 through the connection portion 161 and can support the circuit board member 110 through the mounting portion 162 can be provided according to embodiments.

In some embodiments, the adhesive member 170 may be positioned to selectively elevate the support member 160 relative to the first protection member 120, thereby controlling the vertical offset between the mounting portion 162 and the circuit board member 110. This offset can be configured based on whether the circuit board member 110 is directly supported by the support member 160 or is indirectly supported via the second protection member 150. Such configurability may allow the assembly to accommodate circuit board members of different thicknesses or to adapt to localized component protrusions without causing mechanical stress.

Additionally, in some embodiments, since the mounting portion 162 of the support member 160 may be formed wider than the connection portion 161, the mechanical stability of the support interface may be improved. This wider area can reduce localized pressure on the lower surface of the circuit board member 110 or the second protection member 150, for example, during handling, transportation, or alignment operations. The widened base of the mounting portion 162 also may facilitate consistent positioning and coupling during the assembly process.

By structurally linking the support member 160 to the first protection member 120, rather than to the circuit board member 110 itself, and supporting the non-adhered regions of the board from below, the configuration provided by embodiments of the present disclosure can reduce the likelihood of deformation or damage to the terminal region during handling. This arrangement may be particularly effective when adhesive cannot be applied to the terminal end of the board due to, e.g., contamination risks or mechanical tolerances.

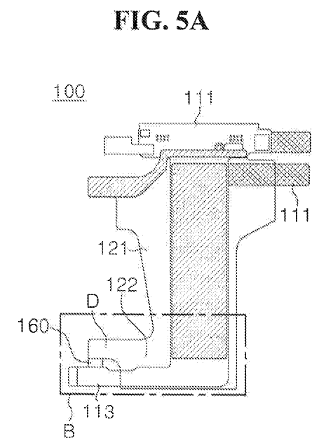

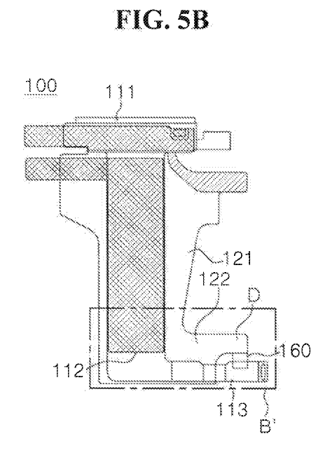

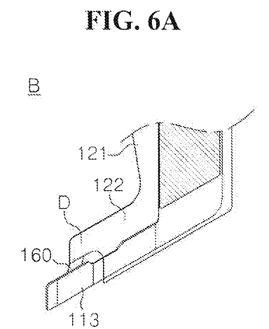

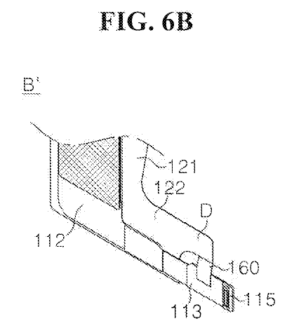

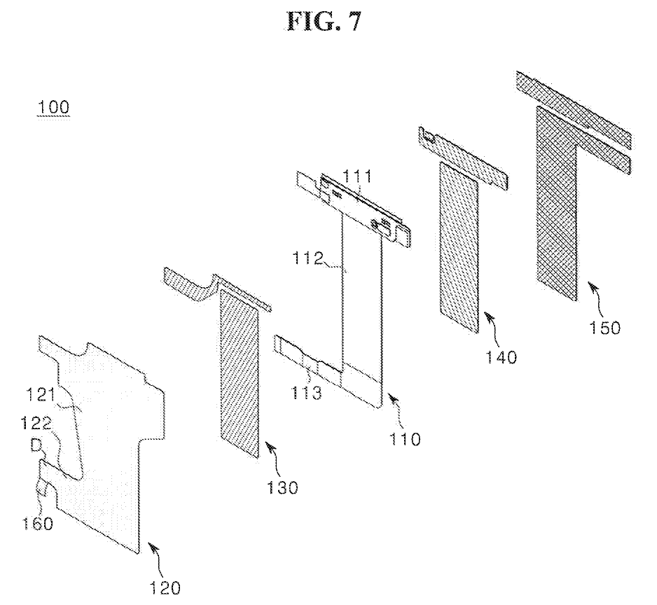

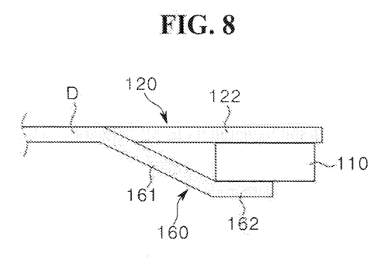

FIG. 5A is a top view of a circuit board assembly according to an embodiment of the present disclosure. FIG. 5B is a bottom view of a circuit board assembly according to an embodiment of the present disclosure. FIG. 6 is an enlarged perspective view of portions B and B’ of FIGS. 5A and 5B. FIG. 7 is an exploded perspective view of a circuit board assembly according to an embodiment of the present disclosure. FIG. 8 schematically illustrates a support structure of a circuit board member 110 by a support member 160 in a circuit board assembly according to an embodiment of the present disclosure.

A structure of a support member 160 of a circuit board member according to an embodiment of the present disclosure is described in detail below with reference to FIGS. 5A-5B and 6 to 8.

First, referring to FIGS. 5A-5B and 6, in an embodiment, a support member 160 may be directly connected to a first protection member 120 disposed on an upper portion of a circuit board member 110. According to an embodiment, an adhesive member 170 is not disposed between the support member 160 and the first protection member 120.

For example, the support member 160 may be described as being formed integrally with the first protection member 120, but is not limited thereto. For example, the support member 160 may be processed separately from the first protection member 120 and then directly attached to a side of the first protection member 120.

The support member 160 may be directly connected to the first protection member 120 at the outside of an edge of the circuit board member 110 and may extend toward a lower surface of the circuit board member 110. For example, the support member 160 may extend from a first dummy area D1 of a first tail protection portion 122 toward a lower surface of a tail portion 113.

The support member 160 may extend across the circuit board member 110 in the vertical direction from an upper surface toward the lower surface of the circuit board member 110.

In this way, in an embodiment, the support member 160 can be mechanically connected to the first protection member 120 without the use of a separate adhesive element, which may facilitate a more streamlined manufacturing process and enable removal of the support member without adhesive residue or added detachment operations. This configuration also may improve structural reliability during handling, transport, or inspection processes by providing a stable connection that may resist degradation over time due to adhesive failure.

Referring to FIG. 8, the support member 160 may be provided in a cantilever shape in which a connection portion 161 is connected to a side of the first protection member 120 (e.g., the first dummy area D1) and a mounting portion 162 is formed as a free end. For example, the support member 160 may elastically support the circuit board member 110 through the connection portion 161 extending from the first protection member 120 toward the circuit board member 110.

For example, the mounting portion 162 may be bent downward so as to be adjacent to the lower surface of the circuit board member 110 while being connected to the first protection member 120 at the outside of the edge of the circuit board member 110.

For example, in a state in which an end of the connection portion 161 is connected to the first protection member 120 at the outside of the edge of the circuit board member 110, the connection portion 161 may be inclined downward toward the circuit board member 110 so that another end of the connection portion 161 is adjacent to the lower surface of the circuit board member 110.

The mounting portion 162 may extend from the other end of the connection portion 161 and support the lower surface of the circuit board member 110. For example, the mounting portion 162 may be disposed in parallel to the downward inclined connection portion 161, and the edge of the lower surface of the circuit board member 110 may be mounted on the mounting portion 162.

For example, the mounting portion 162 may be disposed in parallel to the first protection member 120. That is, the mounting portion 162 may have a selectable angle with respect to the connection portion 161. In this case, the lower surface of the circuit board member 110 may be mounted on the mounting portion 162 so that at least a portion of the lower surface of the circuit board member 110 is in surface contact with the mounting portion 162. For example, the circuit board assembly may be disposed so that the mounting portion 162 is disposed in parallel to the first protection member 120, thereby supporting the circuit board member 110 so that the circuit board member 110 is in surface contact with the mounting portion 162. Hence, the circuit board assembly can prevent the circuit board member 110 from being twisted in a width direction.

As shown in FIG. 8, according to embodiments, by supporting the circuit board member 110 through contact (e.g., direct contact) between the mounting portion 162 and the lower surface of the circuit board member 110, the support member 160 can effectively reduce or prevent deformation, sagging, or twisting of the circuit board member 110. This structural reinforcement may be useful during manufacturing and transport, where external forces or vibrations could otherwise result in warping or breakage. The support structure may allow for mechanical stability without requiring permanent attachment to the circuit board member itself.

The support member 160 according to an embodiment of the disclosure may be removed from the circuit board member 110 together with the first protection member 120 before the circuit board member 110 is coupled to a display panel when the transfer of the circuit board member 110 is completed in the manufacturing process of the display. That is, the circuit board member 110 may be coupled to a back surface of the display panel in a state where the support by the support member 160 is released.

The support member 160 according to embodiments of the present disclosure can prevent sagging by supporting the circuit board member 110 through the structure of the support member 160 disposed on the first protection member 120. In addition, the support member 160 can be easily removed from the circuit board member 110 in the manufacturing process of a display device by not providing a separate adhesive force between the mounting portion 162 and the circuit board member 110 in the support structure of the circuit board member 110.

According to embodiments, the removability of the support member 160 without adhesive bonding may further contribute to manufacturing efficiency by simplifying the separation operation prior to bonding the circuit board member 110 to a display panel. This may avoid the need for additional cleaning, reduce the risk of residue contamination, and allow for the circuit board member to be cleanly coupled to other components during final assembly.

Referring to FIGS. 3 and 7, a second adhesive layer 140 and a second protection member 150 may be disposed on the lower surface of the circuit board member 110.

The second protection member 150 may be attached to the lower surface of the circuit board member 110 through the second adhesive layer 140. The second protection member 150 may be disposed in a plate shape to cover at least a portion of the lower surface of the circuit board member 110. For example, the second protection member 150 may cover a lower surface of a body portion 112 of the circuit board member 110. For example, the second protection member 150 may cover at least a portion of a lower surface of a tail portion 113 together with the lower surface of the body portion 112 of the circuit board member 110.

For example, the second protection member 150 may include a second body protection portion 151 disposed on a lower portion of the body portion 112 of the circuit board member 110 and a second tail protection portion 152 that extends from the second body protection portion 151 and is disposed on a lower portion of the tail portion 113 of the circuit board member 110.

For example, the second body protection portion 151 may cover an area at least wider than a width of the body portion 112, and the second tail protection portion 152 may cover an area at least wider than a width of the tail portion 113.

For example, the first protection member 120 may overlap at least a portion of the circuit board member 110 in the vertical direction. For example, the first protection member 120 may include a second dummy area D2 of which at least a portion is disposed outside the edge of the circuit board member 110, and the second dummy area D2 does not overlap the circuit board member 110 in the vertical direction.

The second protection member 150 may be attached to the lower surface of the circuit board member 110 through the second adhesive layer 140. For example, the second protection member 150 may include a portion that that is not attached to the lower surface of the circuit board member 110 while covering the lower surface of the circuit board member 110. For example, the second protection member 150 may not be attached to a panel coupling portion 111 while covering at least a portion of the panel coupling portion 111 of the circuit board member 110.

For example, the second body protection portion 151 may be attached to the lower surface of the body portion 112.

For example, the second tail protection portion 152 may include a portion that is not attached to the lower surface of the tail portion 113 while covering at least a portion of the lower surface of the tail portion 113. Since the second tail protection portion 152 includes the portion that is not attached to the tail portion 113, the second tail protection portion 152 can prevent deformation or contamination of a terminal part and can allow the second protection member 150 to be easily removed from the lower surface of the circuit board member 110.

In some embodiments, the support member 160 may simultaneously support the second protection member 150, which is attached to the lower surface of the circuit board member 110. For example, when the second tail protection portion 152 is positioned on the tail portion 113, it may rest on the mounting portion 162 of the support member 160. This cooperative engagement between the upper support structure and the lower protection layer may further improve the stability of the circuit board member 110 and can prevent flexure or detachment during movement or handling.

The second protection member 150 may be detachably coupled to the upper surface of the circuit board member 110 through the second adhesive layer 140. The second protection member 150 may be removed from the circuit board member 110 together with the first protection member 120 during the manufacturing process of the display device.

In an embodiment, the second protection member 150 may be supported by the above-described support member 160 while being attached to the lower surface of the circuit board member 110. For example, the circuit board assembly may support the tail portion 113 of the circuit board member 110 as the second tail protection portion 152 of the second protection member 150 is mounted on the mounting portion 162 of the support member 160.

The second protection member 150 can prevent the circuit board member 110 from being damaged by an exposure to an external environment in the transport process of the circuit board member 110.

The second adhesive layer 140 may be applied to the lower surface of the circuit board member 110 to attach the second protection member 150 to the circuit board member 110. For example, the second adhesive layer 140 may be applied to the lower surface of the body portion 112 to attach the second body protection portion 151 to the body portion 112.

For example, the second adhesive layer 140 may be applied to at least a portion of the lower surface of the circuit board member 110. In an embodiment, the second adhesive layer 140 is not applied to a portion of the lower surface of the circuit board member 110. For example, in an embodiment, the second adhesive layer 140 is not applied to the panel coupling portion 111 of the circuit board member 110 and at least a portion of the lower surface of the tail portion 113.

The second adhesive layer 140 may include an organic adhesive, such as, for example, a pressure sensitive adhesive and an optically clear adhesive. For example, the second adhesive layer 140 may include adhesive materials, such as polyurethane-based, polyacrylic-based, polyester-based, polyepoxy-based, and polyvinyl acetate-based, but is not limited thereto.

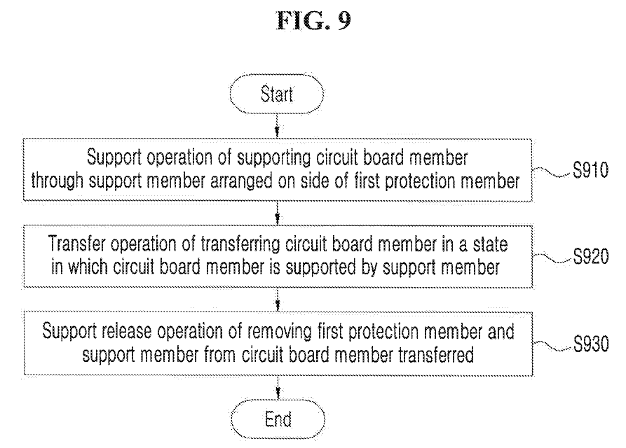

FIG. 9 is a flowchart illustrating a method of manufacturing a display device according to an embodiment of the present disclosure.

A method of manufacturing a display using the circuit board assembly described above is described below with reference to FIG. 9.

A method of manufacturing a display according to the disclosure may include a support operation S910 of supporting at least a portion of a lower surface of a circuit board member 110 through a support member 160 connected to a protection member attached to at least one side of the circuit board member 110.

In an embodiment, in the support operation S910, the support member 160 may be coupled to a side of the circuit board member 110 to support the lower surface of the circuit board member 110.

For example, in the support operation S910, the protection member may be attached to at least one side of an upper surface and the lower surface of the circuit board member 110. For example, a first protection member 120 may be attached to the upper surface of the circuit board member 110 through a first adhesive layer 130. For example, the support member 160 described above may be connected to a side of the first protection member 120.

In addition, in the support operation S910, a second protection member 150 may be attached to the lower surface of the circuit board member 110 through a second adhesive layer 140.

In an embodiment, in the support operation S910, the support member 160 may be connected to the first protection member at the outside of an edge of the circuit board member 110 and may extend toward the circuit board member 110 to support a side of the lower surface of the circuit board member 110.

In the support operation S910, the support member 160 connected to a side of the first protection member 120 may be coupled to the circuit board member 110, thereby supporting the circuit board member 110.

In the support operation S910, the support member 160 may be directly coupled to the lower surface of the circuit board member 110 to support the circuit board member 110. However, the support member 160 is not limited thereto, and the support member 160 may support the circuit board member 110 by being coupled to the second protection member 150 disposed on the lower surface of the circuit board member 110.

For example, in the support operation S910, the support member 160 may be coupled to a side of a tail portion 113 of the circuit board member 110 to which the first protection member 120 is not attached by the first adhesive layer 130.

That is, according to embodiments, in an area (e.g., base portion) of the circuit board member 110 to which the first protection member 120 is attached through the first adhesive layer 130, the circuit board member 110 may be supported by the first protection member 120. In an area (e.g., tail portion 113) of the circuit board member 110 to which the first protection member 120 is not attached, the circuit board member 110 may be supported by the support member 160 by being fastened to the support member 160 connected to the first protection member 120.

For example, in the support operation S910, a process of attaching the first protection member 120 to the circuit board member 110 and a process of fastening the support member 160 to a side of the circuit board member 110 may be performed simultaneously or sequentially.

For example, in the support operation S910, processes of attaching the first protection member 120 and the second protection member 150 to the circuit board member 110 may be performed simultaneously or sequentially.

In the support operation S910 according to embodiments of the present disclosure, the circuit board assembly may be formed by attaching the first protection member 120 and/or the second protection member 150 to the circuit board member 110 and coupling the support member 160 disposed on the first protection member 120 to a side of the circuit board member 110.

The display manufacturing method according to embodiments of the present disclosure may include a transfer operation S920 of transferring the circuit board assembly completed in the support operation S910.

For example, in the transfer operation S920, if the circuit board assembly is completed in the support operation S910, the circuit board member 110 may be transferred in a state where a side of the circuit board member 110 is supported by the support member 160.

That is, in the transfer operation S920, the circuit board assembly formed by attaching the first protection member 120 and the second protection member 150 to the circuit board member 110 and coupling the support member 160 to the side of the circuit board member 110 may be transferred.

For example, in the transfer operation S920, a separately prepared transfer device may be performed by holding the circuit board assembly and moving it to a set position. For example, the transfer device may hold the first protection member 120 attached to the upper surface of the circuit board member 110. For example, the transfer device may hold the first protection member 120 by adsorbing the upper surface of the first protection member 120 at one or more positions, but is not limited thereto.

For example, the transfer operation S920 may be transferred from a first stage in which the assembly of the circuit board assembly is completed to a second stage in which the display panel is mounted and prepared. However, the first stage and the second stage described above are an example, and the positioning in the transfer operation S920 is not limited thereto.

The display manufacturing method according to embodiments of the present disclosure may include a support release operation S930 of removing the first protection member 120 and the support member 160 from the circuit board member 110 where the transfer is completed.

For example, the support release operation S930 may be performed in a state where the circuit board assembly is transferred to the second stage where the display panel is prepared in advance. For example, the support release operation S930 may be performed in a state where the circuit board member 110 is coupled to a back surface of the display panel through a panel connection portion 161, but is not limited thereto.

For example, if the transfer of the circuit board assembly is completed by the transfer device, the first protection member 120 and the second protection member 150 attached to the circuit board member 110 may be removed. For example, the coupling of the support member 160 with respect to the circuit board member 110 or the second protection member 150 attached to the lower surface of the circuit board member 110 may be released, and thus, the support for the circuit board member 110 may be released.

For example, in the support release operation S930, after the connection by the support member 160 is released while the second protection member 150 attached to the lower surface of the circuit board member 110 is removed, the first protection member 120 and the support member 160 connected to the first protection member 120 may be removed. However, embodiments are not limited thereto, and in the support release operation S930, the first protection member 120 and the support member 160 may be first removed, and then the second protection member 150 may be removed, according to an embodiment.

In an embodiment, in a case in which the support member 160 directly supports the circuit board member 110, the support for the circuit board member 110 may be released by removing the first protection member 120 and the support member 160, regardless of the removal order of the second protection member 150.

That is, the circuit board assembly described above can prevent sagging by supporting the circuit board member 110 by the support member 160 in the support operation S910 and the transfer operation S920 of the display manufacturing method according to various embodiments of the present disclosure, and subsequent processes can be continuously performed by removing the first protection member 120 and/or the second protection member 150 and releasing the coupling by the support member 160 in the support release operation S930.

For example, if the support release operation S930 is completed, a bending process may be performed in which the circuit board member 110 is bent so that at least a portion of the circuit board member 110 overlaps the display panel in a stacking direction of the display panel while being attached to the back surface of the display panel. However, it should be understood that the display manufacturing method according to embodiments of the present disclosure includes the support operation S910, the transfer operation S920, and the support release operation S930 described above, and that other processes are not limited by the disclosure. That is, it should be understood that the bending process for the circuit board member 110 may be performed at least simultaneously with the support release operation, or may be performed after the support release operation.

The circuit board assembly according to various embodiments of the present disclosure described above can prevent sagging of the circuit board member that may occur during the display transport process.

In addition, embodiments of the present disclosure can prevent sagging of the circuit board member without a complex device, thereby securing efficiency in the manufacturing cost and the display manufacturing process.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A circuit board assembly, comprising:
a circuit board member;
a first protection member disposed on at least a portion of an upper surface of the circuit board member;
a first adhesive layer disposed between the circuit board member and the first protection member; and
a support member disposed on a side of the first protection member and supporting at least a portion of a lower surface of the circuit board member.

2. The circuit board assembly of claim 1, wherein the support member is connected to the first protection member at an outside of an edge of the circuit board member.

3. The circuit board assembly of claim 1, wherein the support member supports an area of the circuit board member in which the first adhesive layer is not disposed.

4. The circuit board assembly of claim 1, wherein the support member includes:
a mounting portion supporting at least a portion of the lower surface of the circuit board member; and
a connection portion connecting the mounting portion and the first protection member.

5. The circuit board assembly of claim 4, further comprising:
an adhesive member attaching the support member to a lower surface of the first protection member.

6. The circuit board assembly of claim 5, wherein the connection portion is connected to the first protection member through the adhesive member.

7. The circuit board assembly of claim 5, further comprising:
a second protection member covering at least a portion of the lower surface of the circuit board member,
wherein the mounting portion is in contact with the second protection member and supports the circuit board member.

8. The circuit board assembly of claim 5, wherein a thickness of the adhesive member is greater than or about equal to a sum of a thickness of the first adhesive layer and a thickness of the circuit board member.

9. The circuit board assembly of claim 7, wherein the connection portion overlaps the adhesive member in a vertical direction, and
wherein the mounting portion overlaps the second protection member in the vertical direction.

10. The circuit board assembly of claim 5, wherein the mounting portion is disposed in parallel to the first protection member.

11. The circuit board assembly of claim 10, wherein an area of the support member increases as the support member extends from the connection portion to the mounting portion.

12. The circuit board assembly of claim 4, wherein the support member extends from the side of the first protection member toward the lower surface of the circuit board member.

13. The circuit board assembly of claim 12, wherein the connection portion is inclined downward as the connection portion extends from the first protection member to the mounting portion.

14. The circuit board assembly of claim 12, wherein the mounting portion elastically supports the circuit board member through the connection portion.

15. The circuit board assembly of claim 13, wherein a height of the connection portion is greater than or about equal to a sum of a thickness of the first adhesive layer and a thickness of the circuit board member.

16. The circuit board assembly of claim 1, wherein the circuit board member includes a body portion extending in a first direction and a tail portion extending from an end of the body portion in a second direction different from the first direction, and
wherein the support member extends from the side of the first protection member in the first direction and supports the tail portion of the circuit board member.

17. A display device, comprising:
a circuit board member;
a first protection member disposed on at least a portion of an upper surface of the circuit board member;
a first adhesive layer disposed between the circuit board member and the first protection member; and
a support member disposed on a side of the first protection member and supporting at least a portion of a lower surface of the circuit board member.

18. A method of manufacturing a display, the method comprising:
performing a support operation including arranging a first protection member on an upper surface of a circuit board member and supporting at least a portion of a lower surface of the circuit board member through a support member disposed on a side of the first protection member; and
performing a transfer operation of transferring the circuit board member in a state in which a side of the circuit board member is supported by the support member.

19. The method of claim 18, further comprising:
performing a support release operation including removing the first protection member and the support member from the circuit board member on which the transfer is completed.

20. The method of claim 18, wherein in the support operation, the support member is connected to the first protection member at an outside of an edge of the circuit board member, and extends toward and supports the circuit board member.
